(19) United States
(12) Patent Application Publication
(10) Pub. No.: US 2010/0052093 A1
(43) Pub. Date: Mar. 4, 2010

(54) SEMICONDUCTOR SUBSTRATE AND METHOD OF MANUFACTURING THE SAME

(75) Inventor: Takehiro HISATOMI, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/548,762

(22) Filed: Aug. 27, 2009

(30) Foreign Application Priority Data
Sep. 3, 2008 (JP) 2008-225818

(51) Int. Cl. H01L 29/06; H01L 21/762

(52) U.S. Cl. 257/506; 438/423; 257/E29.018; 257/E21.545

(57) ABSTRACT

A semiconductor substrate is a semiconductor substrate used when an SOI substrate having an SOI structure is manufactured, in which a silicon oxide film and a silicon single crystal layer are formed on the surface of a silicon substrate. A region containing no nitrogen, which is made of a silicon single crystal layer with a thickness of 10 μm or less, is formed in the vicinity of the surface, and the nitrogen concentration of a portion excluding the region, that is, the region containing nitrogen, is in a range of 1×10¹³ to 5×10¹⁵ atoms/cm³.

### BACKGROUND OF THE INVENTION

1. Field of the Invention

The present invention relates to a semiconductor substrate and a method of manufacturing the same and, more particularly, to a semiconductor substrate having a Silicon On Insulator (SOI) structure in which a single-crystal silicon layer is formed on an insulating film such as a silicon oxide film, and a method of manufacturing the same.

Priority is claimed on Japanese Patent Application No. 2008-225818, filed Sep. 3, 2008, the content of which is incorporated herein by reference.

2. Description of the Related Art

Recently, as the miniaturization of devices has accelerated with the increased integration of semiconductor circuits, demand for high quality silicon single crystal manufactured by the Czochralski method (hereinafter, referred to as the “CZ method”), which is a source for a substrate, has increased. In addition, there has been demand for an SOI substrate (SOI wafer) having an insulating film such as a silicon oxide film formed just under the surface thereof with low power.

As a method of manufacturing the SOI substrate, a Separation by Ion Implanted Oxygen (SIMOX) method of forming a buried oxide film in a silicon substrate by performing oxygen ion implantation with respect to the silicon substrate is widely used.

Since a device formed in the SOI layer has high radiation resistance, latch-up resistance and short channel effect suppression and can perform an operation with low power consumption, the SOI substrate is expected to be the next-generation high-function semiconductor substrate.

Generally, in a mirror-surface polished substrate obtained by machining silicon single crystal grown according to the CZ method, for example, it is known that crystal defects introduced when growing crystal such as Crystal Originated Particles (COPs) deteriorate the breakdown voltage of a gate oxide film. Accordingly, as a device maker, yield improvement due to the insulation failure of the gate oxide film is accomplished by using a substrate with reduced crystal defect density, for example, a substrate in which single-crystal silicon is epitaxially grown on a silicon substrate or a substrate in which crystal defects are significantly reduced grown by a low-speed pulling-up condition.

The same is true in the SOI substrate. Even in the SOI substrate manufactured by the SIMOX method, COPs or void defects are present in the surface of the substrate or the vicinity of the surface and thus pinhole defects are generated on the surface of the SOI layer of the final product causing the device characteristics to deteriorate. In the SIMOX method, in order to recover irradiation defects due to ion implantation and form a uniform buried oxide film without defects by implanting oxygen, annealing at a high temperature (1300° C. or more) is necessary. Recessed places with a quadrangular pyramid shape or a circular shape and a size of about 10 μm are generated in the surface of the substrate in quantities of several tens or several hundreds/cm².

The recessed places (pits) generated during high-temperature annealing are called thermal pits. These change the film thickness of silicon single crystal on the buried oxide film, destroy the buried oxide film, and further destroy the SOI structure by penetration. Accordingly, devices formed at places where the thermal pits are generated cannot perform their original functions which causes a significant problem when a device is manufactured using the SIMOX wafer.

Accordingly, as a method of manufacturing the SIMOX substrate which does not cause pinhole defects in the surface of the SOI layer, a manufacturing method using silicon single crystal including nitrogen by 1×10¹⁴ atoms/cm³ to 1×10¹⁷ atoms/cm³ was suggested (Japanese Patent Unexamined Publication No. 10-64837).

In this manufacturing method, the generation of defects such as thermal pits generated during high-temperature annealing in the SIMOX method can be suppressed by applying a semiconductor substrate in which a small amount of nitrogen is added into silicon crystal. In order to exhibit this suppression effect, the necessary nitrogen concentration is 1×10¹⁴ atoms/cm³ to 1×10¹⁸ atoms/cm³ before high-temperature annealing and 1×10¹² atoms/cm³ to 1×10¹⁷ atoms/cm³ after high-temperature annealing.

However, if the small amount of nitrogen is present in silicon single crystal, it is known that effects such as (1) the reduction of thermal stress generated by the heating treatment at the time of manufacturing the device and (2) the suppression of the generation of etch pits due to an etchant such as a Secco etchant can be obtained. However, the influence on the generation of the defects during high-temperature annealing used in the SIMOX method is not known. For example, in this method of manufacturing the SOI substrate by implanting oxygen ions into the silicon substrate containing nitrogen and then performing a heating treatment with oxygen gas of 0.5% at 1350° C. for 4 hours and with oxygen concentration of 70% for 4 hours, the number of thermal pits with a size of 0.3 μm or more is 0 in the surface of the SOI layer.

However, even in the manufacturing method of Japanese Patent Unexamined Publication No. 10-64837, defects with a size of less than 0.3 μm are present in the vicinity of the surface of the substrate with high density (for example, see Japanese Patent Unexamined Publication No. 2006-261632).

That is, this phenomenon shows that crystal defects do not disappear in a gas atmosphere with a small oxygen concentration, and thus, in this manufacturing method, the problem remains that defects with a size of less than 0.3 μm do not disappear.

In addition, recently, as the miniaturization of devices is accelerated with the increased integration of semiconductor circuits, the defects with a size of less than 0.3 m become fatal defects in the subsequent device processes.

The present invention is contrived to solve the above-described problems. An object of the invention is to provide a semiconductor substrate without defects with a relatively small size in a surface used when manufacturing an SOI substrate having an SOI structure, and a method of manufacturing the semiconductor substrate.

### SUMMARY OF THE INVENTION

A semiconductor substrate according to the present invention is a semiconductor substrate used when an SOI substrate having an SOI structure is manufactured, in which a silicon oxide film and a silicon single crystal layer are sequentially formed on the surface of a silicon substrate, and includes a region containing no nitrogen in the vicinity of the surface.

According to the semiconductor substrate of the present invention, since the region containing no nitrogen is formed in the vicinity of the surface, it is possible to prevent electrically active defects, such as pinhole defects, from being generated in the surface due to the coupling between nitrogen and oxygen. Accordingly, if the SOI substrate is manufactured using this semiconductor substrate, it is possible to maintain the good characteristics of a device formed on this SOI substrate and to improve the reliability of the device.

In the semiconductor substrate of the present invention, the region may be a silicon single crystal layer containing no nitrogen with a thickness of 10 μm or less, which is subjected to a heating treatment at a temperature in the range of 1000 to 1280° C. in an inert gas and/or reducing gas atmosphere.

In this case, since the region is a silicon single crystal layer containing no nitrogen with the thickness of 10 μm or less, which is subjected to the heating treatment at the temperature in the range of 1000 to 1280° C. in the inert gas and/or reducing gas atmosphere, it is possible to prevent defects such as thermal pits with a small size from being generated in the surface and to improve the in-plane uniformity of this silicon single crystal layer.

In the semiconductor substrate of the present invention, the region may be a silicon single crystal layer containing no nitrogen with a thickness of 10 μm or less, which is formed by an epitaxial method.

In this case, since the region is a silicon single crystal layer containing no nitrogen with a thickness of 10 μm or less, which is formed by an epitaxial method, it is possible to prevent defects such as thermal pits with a small size from being generated in the surface and to improve the in-plane uniformity of this silicon single crystal layer.

In the semiconductor substrate of the present invention, the nitrogen concentration of a portion excluding the region may be in the range of 1×10¹³ to 5×10¹⁵ atoms/cm³.

In this case, since the nitrogen concentration of the portion excluding the region is in the range of 1×10¹³ to 5×10¹⁵ atoms/cm³, it is possible to improve the in-plane uniformity of BMD density in the surface of the region containing no nitrogen and to accelerate the growth of oxygen precipitate in this surface.

A method of manufacturing a semiconductor substrate according to the present invention uses a semiconductor substrate having a region containing no nitrogen in the vicinity of a surface thereof, in the method of manufacturing the semiconductor substrate by implanting oxygen ions into a silicon single crystal substrate and forming a buried oxide film in the silicon single crystal silicon.

According to the method of manufacturing the semiconductor substrate of the present invention, since the semiconductor substrate having the region containing no nitrogen in the vicinity of the surface thereof is used, it is possible to manufacture a semiconductor substrate in which electrically active defects, such as pinhole defects, are not generated in the surface thereof due to coupling between nitrogen and oxygen.

### BRIEF DESCRIPTION OF THE DRAWINGS

FIG. 1 is a cross-sectional view showing a semiconductor substrate according to an embodiment of the present invention.

FIG. 2 is a view showing a method of manufacturing a semiconductor substrate and an SOI substrate according to an embodiment of the present invention.

FIG. 3 is a view showing an example of the profile of a heating treatment in a gas mixture atmosphere of argon and oxygen.

FIG. 4 is a cross-sectional view showing an SOI substrate manufactured using a semiconductor substrate according to an embodiment of the present invention.

### DETAILED DESCRIPTION OF THE INVENTION

The best mode for carrying out a semiconductor substrate and a method of manufacturing the same according to the present invention will be described. This embodiment is described in detail in order to facilitate the understanding of the spirit of the invention and does not restrict the present invention unless otherwise specified.

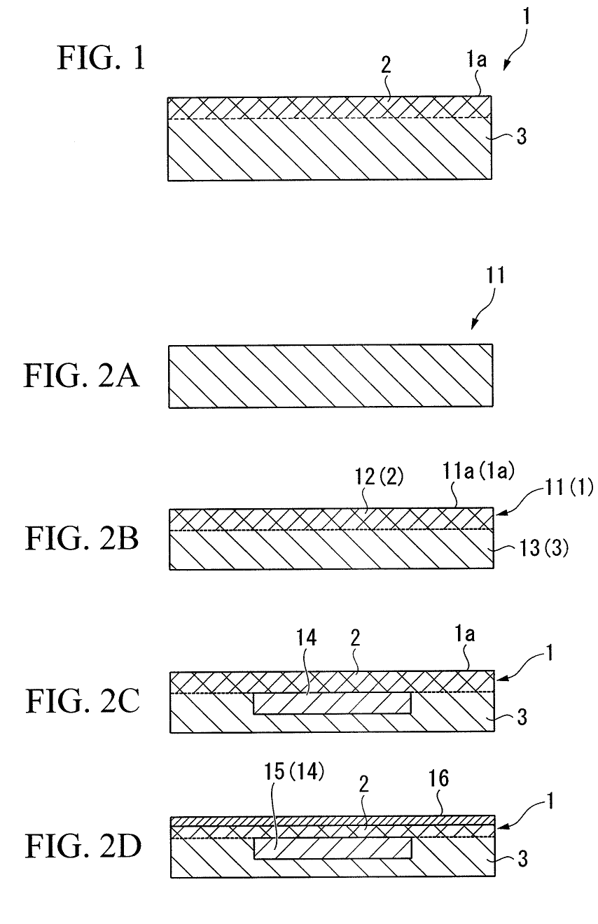

FIG. 1 is a cross-sectional view showing a semiconductor substrate according to an embodiment of the present invention. In the figure, 1 denotes a semiconductor substrate, and a region 2 containing no nitrogen is formed in the vicinity of a surface 1a of the semiconductor substrate 1.

The semiconductor substrate 1 is, for example, a silicon substrate obtained by machining silicon single crystal manufactured by a CZ method in a wafer shape, to which a p-type dopant such as boron (B) or an n-type dopant such as phosphorus (P) is added.

This silicon single crystal may be manufactured by putting polycrystal silicon and nitride such as silicon nitride into a crucible of a CZ growth furnace, melting them to a polycrystal silicon melt, bringing silicon seed crystal into contact with the polycrystal silicon melt, and pulling up the silicon seed crystal.

The region 2 containing no nitrogen is composed of a silicon single crystal layer of the following (1) or (2).

(1) A silicon single crystal layer containing no nitrogen, which is obtained by performing a heating treatment at a temperature of a range of 1000 to 1280° C. and preferably a range of 1200 to 1250° C. in an inert gas and/or reducing gas atmosphere with respect to the vicinity of the surface 1a of the semiconductor substrate 1.

(2) A silicon single crystal layer containing no nitrogen, which is formed on the surface 1a of the semiconductor substrate 1 by an epitaxial method.

The thickness of the silicon single crystal is preferably equal to or less than 10 m or less, more preferably equal to or more than 0.5 μm and equal to or less than 8 μm, and further more preferably equal to or more than 1 μm and equal to or less than 2.5 μm.

The reason why the thickness of the silicon single crystal layer must be equal to or less than 10 μm is so that defects with a relatively small size of less than 0.3 μm in the surface of the SOI substrate obtained when manufacturing the SOI substrate having the SOI structure using the semiconductor substrate 1 can be reduced.

The nitrogen concentration of a portion excluding the region 2 containing no nitrogen in the semiconductor substrate 1, that is, a region 3 containing nitrogen, is in a range of 1×10¹³ to 5×10¹⁵ atoms/cm³ and preferably 5×10¹⁴ to 1×10¹⁵ atoms/cm³.

The reason why the nitrogen concentration is preferably in the range of 1×10¹³ to 5×10¹⁵ atoms/cm³ is so that BMD density becomes uniform over the entire surface of the surface 1a of the semiconductor substrate 1 and thus the growth of oxygen precipitate is accelerated. If the nitrogen concentration exceeds 5×10¹⁵ atoms/cm³, the nitrogen concentration becomes close to the limit of the capacity of the silicon single crystal to contain nitrogen from solubility and thus the concentration is difficult to uniformly maintain over the entire length of the silicon single crystal.

The nitrogen concentration is a value computed from the segregation coefficient of nitrogen based on the initial silicon melt amount, the amount of nitrogen which is initially added to the silicon melt, and the extraction position of a wafer relative to an ingot.

Next, the method of manufacturing the semiconductor substrate 1 and the SOI substrate according to the present embodiment will be described with reference to FIG. 2.

First, as shown in FIG. 2A, a semiconductor substrate 11 made of silicon single crystal in which the nitrogen concentration is in the range of 1×10¹³ to 5×10¹⁵ atoms/cm³ is prepared.

It is preferable that nitrogen is uniformly introduced into the whole of this semiconductor substrate 11.

Subsequently, as shown in FIG. 2B, this semiconductor substrate 11 is subjected to a heating treatment at a temperature in a range of 1000 to 1280° C. and more preferably a temperature in a range of 1200 to 1250° C. for 5 minutes to 4 hours and preferably 60 minutes to 2 hours in an inert gas and/or reducing gas atmosphere. The vicinity of the surface 11a of this semiconductor substrate 11 becomes a silicon single crystal layer 12 containing no nitrogen with a thickness equal to or more than 10 μm.

An Ar gas atmosphere is suitable as the inert gas atmosphere.

This silicon single crystal layer 12 may be manufactured by depositing a silicon single crystal layer on the surface 11a of the semiconductor substrate 11 by an epitaxial method.

The nitrogen concentration of a portion excluding the silicon single crystal layer 12 in this semiconductor substrate 11, that is, silicon single crystal 13 containing nitrogen, is in a range of 1×10¹³ to 5×10¹⁵ atoms/cm³ and preferably 5×10¹⁴ to 1×10⁵ atoms/cm³.

However, in the invention of Japanese Patent Unexamined Publication No. 10-64837 of the conventional example, if high-temperature annealing is performed in order to form the buried oxide film in the silicon wafer, point defects such as vacancies generated in the surface by the high-temperature annealing so as to be increased to a heat equilibrium concentration, and defects generated in the surface of the silicon wafer and the vicinity of the surface when growing the crystal of the silicon wafer or when implanting oxygen ions aggregate to form thermal pits.

If nitrogen is added to silicon crystal, it is possible to suppress the formation of the thermal pits by the diffusion of the point defects or the point defect concentration generated in the crystal. Meanwhile, since nitrogen may be coupled with oxygen so as to form electrically active defects, it is preferable that nitrogen is not present in the silicon crystal layer on the buried oxide film in which the device is formed.

Accordingly, in the present embodiment, the silicon single crystal layer 12 containing no nitrogen with the thickness equal to or less than 10 μm is formed by performing the heating treatment with respect to the vicinity of the surface 1a of the semiconductor substrate 11 at the temperature in the range of 1000 to 1280° C. for 5 minutes to 4 hours in the inert gas and/or reducing gas atmosphere or depositing the silicon single crystal layer on the surface 11a of the semiconductor substrate 11 by the epitaxial method, using the semiconductor substrate 11 made of silicon single crystal in which the nitrogen concentration is in the range of 1×10¹³ to 5×10¹⁵ atoms/cm³.

The silicon single crystal layer 12 in the vicinity of the surface in which nitrogen is not present in each method is the region including the buried oxide film in which the device is prepared.

By the above method, the region 2 made of the silicon single crystal layer with the thickness equal to or less than 10 μm and containing no nitrogen can be formed on the vicinity of the surface 1a or the surface 1a so as to manufacture the semiconductor substrate 1 in which the nitrogen concentration of the portion excluding the region 2 containing no nitrogen, that is, the region 3 containing nitrogen is in the range of 1×10¹³ to 5×10¹⁵ atoms/cm³.

In the surface of the semiconductor substrate 1, the number of defects such as thermal pits with a small size of less than 0.3 μm is extremely small and in-plane uniformity is high.

By performing the heating treatment with respect to the vicinity of the surface 1a of the semiconductor substrate 11 at the temperature in the range of 1000 to 1280° C. for 5 minutes to 4 hours in the inert gas and/or reducing gas atmosphere, an inner wall oxide film of a void defect called a crystal defect caused by the heating treatment under a non-oxidizing gas atmosphere and, more particularly, a grown-in defect is melted, and, thereafter, the grown-in defect in the vicinity of the surface is reduced and caused to disappear by the hole filling due to the diffusion of silicon atoms between lattices in the void defect in which the inner wall oxide film is removed such that the silicon single crystal layer 12 containing no nitrogen with 10 μm or less can be formed.

Subsequently, the SOI substrate is manufactured using the semiconductor substrate 1 by the SIMOX method.

As shown in FIG. 2C, oxygen ions are implanted from the surface 1a into the semiconductor substrate 1 such that a high-concentration oxygen ion implantation layer 14 is formed from the surface 1a of the silicon substrate 1 with a predetermined depth, for example, 100 nm to 1000 nm and preferably 200 nm to 800 nm.

Subsequently, a heating treatment is performed at a temperature in the range of 1300 to 1380° C. for 240 to 1500 minutes in a gas mixture atmosphere of argon and oxygen. As the gas mixture, for example, a gas mixture such as 0.5 v/v % O₂−99.5 v/v % Ar or 70 v/v % O₂−30 v/v % Ar is preferable.

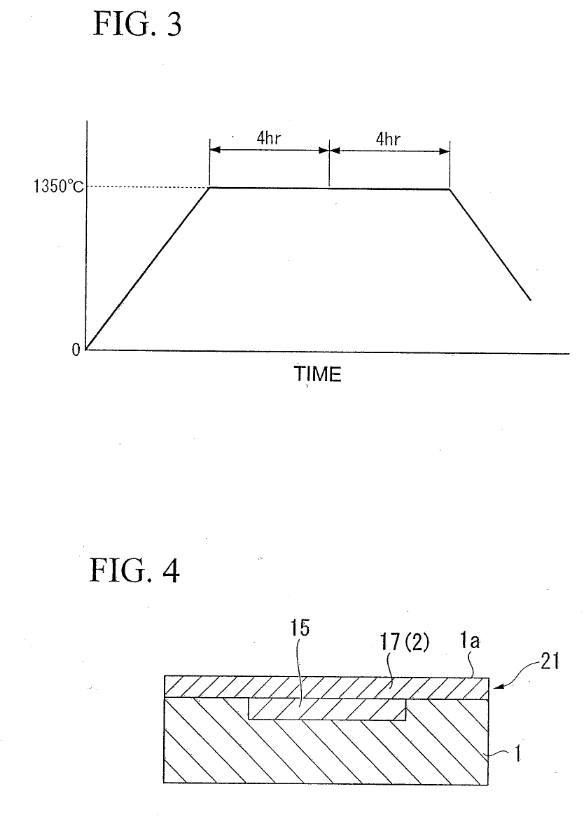

FIG. 3 shows an example of the profile of the heating treatment.

In the profile of the heating treatment, the heating treatment is performed at 1350° C. for 4 hours in the gas mixture atmosphere of 0.5 v/v % O₂−99.5 v/v % Ar and, subsequently, the gas mixture atmosphere of 70 v/v % O₂−30 v/v % Ar is set by gas replacement and the heating treatment is performed at 1350° C. for 4 hours in this atmosphere.

Accordingly, the surface of the silicon substrate 1 including the high-concentration oxygen ion implantation layer 14 is oxidized such that, as shown in FIG. 2D, the high-concentration oxygen ion implantation layer 14 becomes a buried oxide film 15, and a silicon oxide film 16 is formed on the region 2 containing no nitrogen in the vicinity of the surface 1a of the silicon substrate 1.

Subsequently, an etching process is performed with respect to the silicon oxide film 16 using an etchant such as a hydrogen fluoride aqueous solution, and the silicon oxide film 16 is removed.

Subsequently, the region 2 containing no nitrogen, in which the silicon oxide film 16 is removed, is washed with SC-1 such that impurities are removed.

By the above process, as shown in FIG. 4, the SOI substrate 21 having the SOI structure, in which the buried oxide film 15 and a silicon single crystal layer 17 made of the region 2 containing no nitrogen are sequentially formed in the vicinity of the surface 1a of the semiconductor substrate 1, can be manufactured.

In the SOI substrate 21, defects with a size of less than 0.3 μm can be reduced.

As described above, it is possible to manufacture the SOI substrate 21 in which pits are hardly generated at the time of high-temperature annealing and defects are hardly generated in the SOI structure.

### EXAMPLES

Hereinafter, the present invention will be described using embodiments.

### Example 1

Polycrystal silicon was put into a crucible of a CZ growth furnace and was heated and melted, and nitrogen gas was introduced into the polycrystal silicon melt such that silicon single crystal including nitrogen of 1×10¹⁴ atoms/cm³ was obtained. The silicon single crystal was machined in a wafer shape, and the silicon single crystal layer was deposited on the obtained silicon wafer by the epitaxial method such that the deposition amount thereof became 2 μm in the vicinity of the surface, thereby manufacturing a silicon substrate of 300 mmφ of Example 1.

Subsequently the SOI substrate was manufactured by the SIMOX method. First, oxygen ions were implanted into the silicon substrate with implantation energy of 180 KeV and dose amount of 4.0×10¹⁷ cm⁻² so as to form a high-concentration ion implantation layer with a predetermined depth.

Subsequently, the silicon substrate was put into the gas mixture atmosphere of 0.5 v/v % O₂−99.5 v/v % Ar of 600° C. and was heated up to 1350° C. so as to perform a heating treatment at 1350° C. for 4 hours, a heating treatment was performed at 1350° C. for 4 hours in a gas mixture atmosphere of 70 v/v % O₂−30 v/v % Ar, and the temperature was decreased to 600° C.

Subsequently, a surface oxide film was removed by a HF aqueous solution and SC-1 washing was performed, thereby manufacturing an SOI substrate of Example 1. The thickness of the silicon single crystal layer on the surface of the SOI substrate was about 160 nm and the thickness of the buried oxide film was 110 nm.

The number of thermal pits generated in the surface of the SOI substrate was measured by a particle counter. At this time, the number of pits of 0.3 μm or more in the whole silicon substrate of 300 mmφ was 0 and the number of pits of 0.09 μm or more was 30 or less.

Even in the observation of the surface of the silicon substrate using an optical microscope, the generation of the thermal pits was not observed.

It is possible to completely suppress the generation of the thermal pits by the introduction of nitrogen and to reduce the nitrogen concentration of the surface to a degree which does not have an influence on the manufacture of the device.

### Example 2

Polycrystal silicon was put into a crucible of a CZ growth furnace and was heated and melted, and nitrogen gas was introduced into the polycrystal silicon melt such that silicon single crystal including nitrogen of 1×10¹⁴ atoms/cm³ was obtained. The silicon single crystal was machined in a wafer shape, and a heating treatment was performed with respect to the obtained silicon wafer at 1200° C. for 1 hour under a 100 v/v % Ar atmosphere, thereby manufacturing a silicon substrate of 300 mmφ of Example 2, in which a grown-in defect was reduced and caused to disappear with a depth of 10 μm in the vicinity of the surface.

Subsequently, an SOI substrate of Example 2 was manufactured using this silicon substrate by the SIMOX method, similar to Example 1.

The thickness of the silicon single crystal layer on the surface of the SOI substrate was about 160 nm and the thickness of the buried oxide film was 110 nm.

The number of thermal pits generated in the surface of the SOI substrate was measured by a particle counter. At this time, the number of pits of 0.3 μm or more in the whole silicon substrate of 300 mmφ was 0 and the number of pits of 0.09 μm or more was 30 or less.

Even in the observation of the surface of the silicon substrate using an optical microscope, the generation of the thermal pits was not observed.

It is possible to completely suppress the generation of the thermal pits by the introduction of nitrogen and to reduce the nitrogen concentration of the surface to a degree which does not have an influence on the manufacture of the device.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor substrate used when an SOI substrate having an SOI structure is manufactured, the semiconductor substrate comprising:
a silicon oxide film;
a region containing no nitrogen in the vicinity of a surface;
a buried oxide film; and
silicon single crystal.

2. The semiconductor substrate according to claim 1, wherein a region is a silicon single crystal layer containing no nitrogen with a thickness of 10 μm or less, which is subjected to a heating treatment at a temperature in a range of 1000 to 1280° C. in an inert gas and/or reducing gas atmosphere.

3. The semiconductor substrate according to claim 1, wherein a region is a silicon single crystal layer containing no nitrogen with a thickness of 10 μm or less, which is formed by an epitaxial method.

4. The semiconductor substrate according to claim 1, wherein the nitrogen concentration of a portion excluding the region is in a range of 1×10¹³ to 5×10¹⁵ atoms/cm³.

5. A method of manufacturing a semiconductor substrate, the method comprising:
preparing a silicon single crystal substrate;
preparing a region containing no nitrogen in the vicinity of a surface of the silicon single crystal substrate;
implanting oxygen ions into the silicon single crystal substrate; and
forming a buried oxide film in the silicon single crystal substrate.
